(19) United States
(12) Patent Application Publication
(10) Pub. No.: US 2025/0239466 A1
(43) Pub. Date: Jul. 24, 2025

(54) WAFER CLEANING SYSTEM

(71) Applicant: Samsung Electronics Co., Ltd., Suwon-si (KR)

(72) Inventors: Tae Ha YOON, Suwon-si (KR); Jun-Youl YANG, Suwon-si (KR); JIN-I LEE, Suwon-si (KR)

(21) Appl. No.: 18/959,770

(22) Filed: Nov. 26, 2024

(30) Foreign Application Priority Data
Jan. 18, 2024 (KR) 10-2024-0007875

(51) Int. Cl. H01L 21/67; H01L 21/677

(52) U.S. Cl. CPC H01L 21/67057; H01L 21/67034; H01L 21/67706; H01L 21/67718

(57) ABSTRACT

A wafer cleaning system comprising a processing bath group including a first Standard Clean (SC) processing bath, a first Hot Quick Dump Rinse (HQDR) processing bath and a second SC processing bath, which are disposed side by side in a first direction, and a first wafer transferring unit including a first rail guide extended in the first direction and a first driving unit on the first rail guide to move in the first direction along the first rail guide, and including a first arm configured to support the wafer group and rotate in a state that it supports the wafer group, and a second wafer transferring unit including a second rail guide extended in a second direction and a second driving unit mounted on the second rail guide to move in the second direction along the second rail guide, and including a support unit for supporting the wafer group.

### CROSS-REFERENCE TO RELATED APPLICATION

This application claims priority under 35 U.S.C. § 119 from Korean Patent Application No. 10-2024-0007875, filed on Jan. 18, 2024, in the Korean Intellectual Property Office and all the benefits accruing therefrom under 35 U.S.C. § 119, the contents of which in its entirety are herein incorporated by reference.

### BACKGROUND

### Technical Field

The present disclosure relates to a wafer cleaning system, and more particularly, to a wafer cleaning system capable of improving performance and reliability of a wafer, for which a cleaning process is completed, by mitigating a decrease in an etch amount due to by-products accumulated inside a processing bath and mitigating imbalance in process distribution on a wafer surface.

### Description of the Related Art

A wet cleaning process essential in a semiconductor manufacturing process is a process of etching a hard mask or the like on a wafer by a chemical solution of a high temperature. This wet cleaning process has been performed by batch equipment in the conventional method. The batch equipment refers to equipment for wet cleaning a set of wafers by simultaneously precipitating a plurality of wafers in a chemical solution instead of one wafer.

In case of such batch equipment, problems such as flow defects and deterioration of dispersion uniformity may occur on the wafer. In addition, an etch rate (E/R) may vary depending on a region of a surface of one wafer.

### BRIEF SUMMARY

An object of the present disclosure is to provide a wafer cleaning system capable of improving performance and reliability of a wafer for which a cleaning process has been completed.

The objects of the present disclosure are not limited to those mentioned above and additional objects of the present disclosure, which are not mentioned herein, will be clearly understood by those skilled in the art from the following description of the present disclosure.

According to an aspect of the present disclosure, there is provided a wafer cleaning system comprising a processing bath group including a first Standard Clean (SC) processing bath, a first Hot Quick Dump Rinse (HQDR) processing bath, and a second SC processing bath, which are disposed side by side in a first direction, and a first wafer transferring unit including a first rail guide extended in the first direction and a first driving unit mounted on the first rail guide and configured to move in the first direction along the first rail guide, the first driving unit including a first arm configured to support a wafer group and rotate in a state that it supports the wafer group, and a second wafer transferring unit including a second rail guide extended in a second direction intersecting the first direction and a second driving unit mounted on the second rail guide and configured to move in the second direction along the second rail guide, the second driving unit including a support unit for supporting the wafer group by receiving the wafer group from the first arm, wherein the first wafer transferring unit is configured to rotate the wafer group in a fourth direction with respect to a third direction intersecting the first and second directions as a central axis while moving the wafer group cleaned in the first SC processing bath and the first HQDR processing bath toward the second SC processing bath along the first direction.

According to an aspect of the present disclosure, there is provided a wafer cleaning system comprising a processing bath group including a first Standard Clean (SC) processing bath, a first Hot Quick Dump Rinse (HQDR) processing bath, and a second SC processing bath, which are disposed side by side in a first direction, a first wafer transferring unit including a first rail guide extended in the first direction and a first driving unit mounted on the first rail guide and configured to move in the first direction along the first rail guide, the first driving unit including a first arm configured to support a wafer group, and a second wafer transferring unit including a second rail guide extended in a second direction intersecting the first direction and a second driving unit mounted on the second rail guide and configured to move in the second direction along the second rail guide, the second driving unit including a second arm configured to support the wafer group by receiving the wafer group from the first arm and rotate in a state that it supports the wafer group, wherein the second wafer transferring unit is configured to rotate the wafer group inside any one of the first SC processing bath and the first HQDR processing bath in a fourth direction with respect to a third direction intersecting the first direction and the second direction as a central axis, and wherein the first wafer transferring unit is configured to move the wafer group cleaned in the first SC processing bath and the first HQDR processing bath toward the second SC processing bath along the first direction.

According to an aspect of the present disclosure, there is provided a wafer cleaning system comprising a processing bath group including a first Standard Clean (SC) processing bath, a first Hot Quick Dump Rinse (HQDR) processing bath, a second SC processing bath, and a second HQDR processing bath, which are disposed side by side in a first direction, a first wafer transferring unit including a first rail guide extended in the first direction and a first driving unit mounted on the first rail guide and configured to move in the first direction along the first rail guide, the first driving unit including a first arm configured to support the wafer group and rotate in a state that it supports the wafer group, a second wafer transferring unit including a second rail guide extended in a second direction intersecting the first direction and a second driving unit mounted on the second rail guide and configured to move in the second direction along the second rail guide, the second driving unit including a second arm configured to support the wafer group by receiving the wafer group from the first arm and rotate in a state that it supports the wafer group, and a third wafer transferring unit including a third rail guide extended in the second direction and a third driving unit mounted on the third rail guide and configured to move in the second direction along the third rail guide, the third driving unit including a third arm configured to support the wafer group by receiving the wafer group from the first arm and rotate in a state that it supports the wafer group, wherein at least one of the first to third wafer transferring units is configured to rotate the wafer group with respect to a third direction intersecting the first direction and the second direction as a central axis.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is an exemplary view illustrating a wafer cleaning system according to some example embodiments.

FIG. 2 is an example view illustrating a first wafer transferring unit according to example embodiments.

FIG. 3 is an enlarged view illustrating a portion I of FIG. 2.

FIG. 4 is an enlarged view illustrating a portion II of FIG. 3.

FIG. 5 is an example view illustrating a second wafer transferring unit according to example embodiments.

FIG. 6 is an enlarged view illustrating a portion III of FIG. 5.

FIGS. 7 and 8 are example views illustrating a second wafer transferring unit according to some other example embodiments.

FIGS. 9 to 12 are example views illustrating a wafer cleaning system according to some example embodiments.

FIGS. 13 to 26 are example views illustrating a wafer cleaning operation of a wafer cleaning system according to some example embodiments.

FIGS. 27 to 29 are example views illustrating a wafer cleaning operation of a wafer cleaning system according to some other example embodiments.

FIGS. 30 to 38 are example views illustrating a wafer cleaning operation of a wafer cleaning system according to some other example embodiments.

FIG. 39 is an example view illustrating a wafer cleaning operation of a wafer cleaning system according to some other example embodiments.

FIG. 40 is an example view illustrating a wafer cleaning operation of a wafer cleaning system according to some other example embodiments.

FIG. 41 is an example view illustrating an effect of a wafer cleaning system according to some example embodiments.

### DETAILED DESCRIPTION OF THE DISCLOSURE

Hereinafter, a wafer cleaning system according to some embodiments will be described with reference to the accompanying drawings. Like reference characters refer to like elements throughout.

In the drawings, the size and relative sizes of layers and regions may be exaggerated for clarity. Like numbers refer to like elements throughout. Though the different figures show variations of exemplary embodiments, these figures are not necessarily intended to be mutually exclusive from each other. Rather, as will be seen from the context of the detailed description below, certain features depicted and described in different figures can be combined with other features from other figures to result in various embodiments, when taking the figures and their description as a whole into consideration.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

In the following description, a first direction X may be any one of horizontal directions. A second direction Y may be any one of horizontal directions different from the first direction X. The second direction Y may cross the first direction X. For example, the second direction Y may be perpendicular to the first direction X. A third direction Z may cross the first direction X and the second direction Y. The third direction Z may be perpendicular to both the first direction X and the second direction Y. The third direction Z may be, for example, a vertical direction. Therefore, the first direction X, the second direction Y and the third direction Z may be orthogonal to one another.

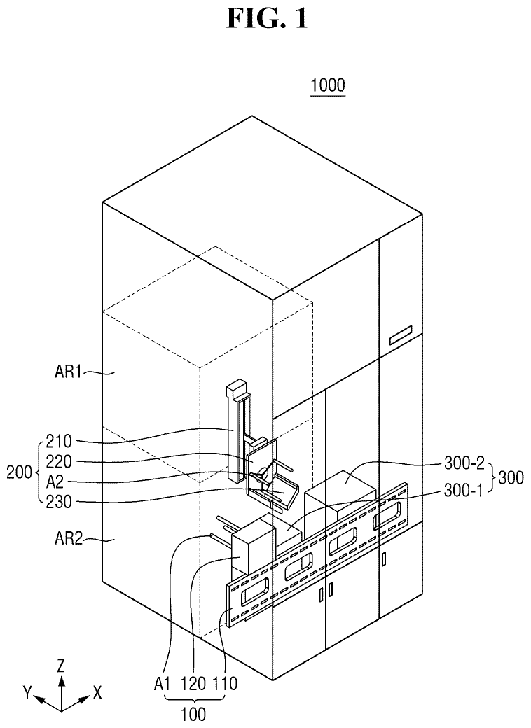

FIG. 1 is an example view illustrating a wafer cleaning system according to some example embodiments.

Referring to FIG. 1, a wafer cleaning system 1000 may include a processing bath group 300, a first wafer transferring unit 100, and a second wafer transferring unit 200.

The wafer cleaning system 1000 may be a batch type cleaning system. For example, the wafer cleaning system 1000 may perform cleaning by dipping a plurality of wafers into any one processing bath 300-1 or 300-2 included in the processing bath group 300 simultaneously. The processing bath group 300 may include a plurality of processing baths 300-1 and 300-2. Although FIG. 1 shows that only two processing baths are included in the processing bath group 300, the processing bath group 300 may include three or more processing baths. The plurality of processing baths 300-1 and 300-2 included in the processing bath group 300 may be aligned in the first direction X and disposed side-by-side to each other.

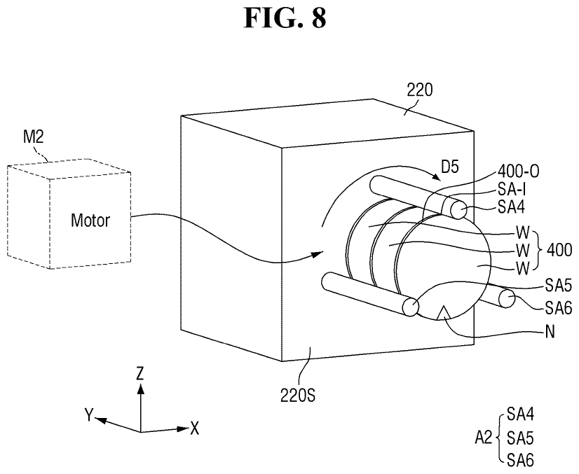

A processing liquid for performing a certain processing for a wafer may be contained in each processing bath. The processing bath may be divided into a chemical solution bath and a rinsing bath. In the chemical solution bath, wafer cleaning, photoresist delamination, and etching processing may be performed. In the rinsing bath, a process of cleaning the wafer that has been completely processed in the chemical solution bath may be performed. The processing bath group 300 will be described later with reference to FIG. 8.

The first wafer transferring unit 100 may be spaced apart from the processing bath group 300 in the second direction Y. The first wafer transferring unit 100 may include a first rail guide 110 and a first driving unit 120. The first rail guide 110 may be extended lengthwise in the first direction X along the processing bath group 300 aligned and disposed in the first direction X. The first rail guide 110 may serve as a guide for the first driving unit 120 to move along the first direction X.

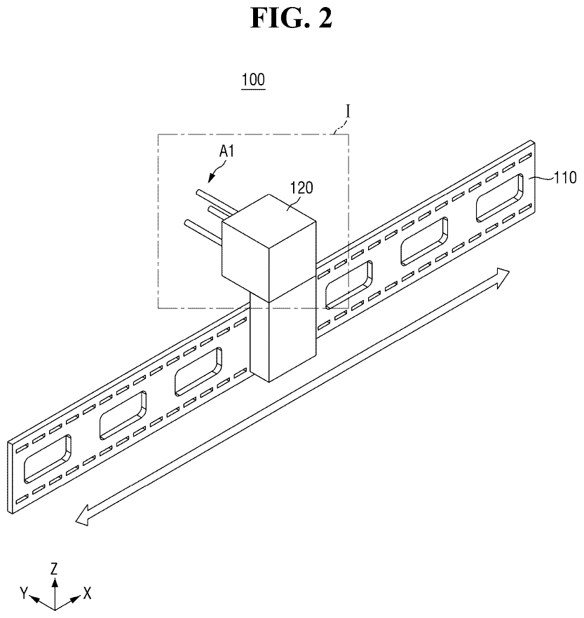

The first driving unit 120 may be mounted on the first rail guide 110. The first driving unit 120 may move in the first direction X along the first rail guide 110 in a state that it is mounted on the first rail guide 110. The first driving unit 120 may also move in an opposite direction of the first direction X depending on the operation. A first arm A1 may be mounted on one surface of the first driving unit 120. The first arm A1 may be configured to support a wafer group that includes a plurality of wafers. The first driving unit 120 may move on the first rail guide 110 in a state that the wafer group is seated on the first arm A1. Therefore, the first wafer transferring unit 100 may transfer the wafer group from one of the plurality of processing baths 300-1 and 300-2 included in the processing bath group 300 to the other of the processing bath 300-1 and 300-2 included in the processing bath group 300. The first wafer transferring unit 100 will be described later with reference to FIG. 2, and the like.

The second wafer transferring unit 200 may be positioned on the processing bath group 300. For example, the second wafer transferring unit 200 may be positioned above the processing bath group 300. The second wafer transferring unit 200 may include a second rail guide 210, a second driving unit 220, a support unit 230, and a second arm A2. The second rail guide 210 may be extended in the third direction Z. The second rail guide 210 may provide a guide for the second driving unit 220 to move in the third direction Z. The second driving unit 220 may be connected to the second rail guide 210 and may move in the third direction Z and its opposite direction. The second arm A2 may be mounted on one surface of the second driving unit 220. The second arm A2 may be configured to support the wafer group.

For example, when the first driving unit 120 supporting the wafer group with the first arm A1 moves along the first direction X and is positioned in front of the second wafer transferring unit 200, the first driving unit 120 may stop. In this case, after moving in the opposite direction of the third direction Z, the second driving unit 220 may receive the wafer group supported by the first arm A1 through the second arm A2. The second driving unit 220 may move in the opposite direction of the third direction Z in a state that the second arm A2 supports the wafer group received from the first arm A1. Therefore, the wafer group may be accommodated in the processing bath 300-1 or 300-2. The wafer group accommodated in the processing bath 300-1 or 300-2 may be subjected to a wafer processing process such as a wafer cleaning process and an etching process depending on the type of the processing liquid included in the processing bath.

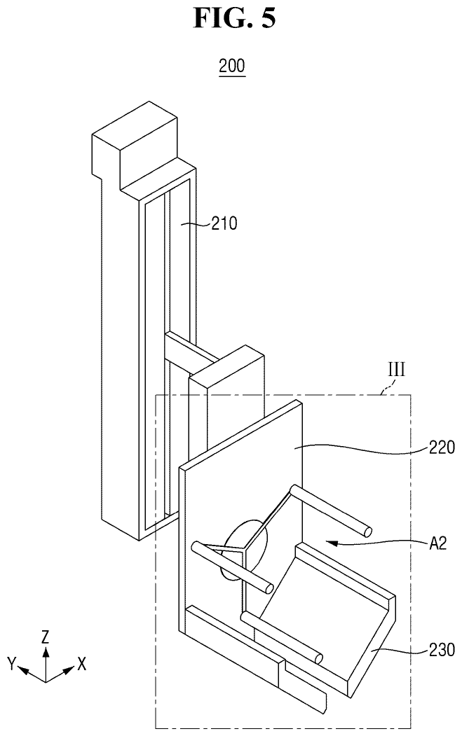

The support unit 230 may be mounted on one surface of the second driving unit 220. The support unit 230 may be disposed below the second arm A2. The support unit 230 may perform a role similar to that of the second arm A2. For example, the support unit 230 may receive the wafer group from the first arm A1 of the first wafer transferring unit 100, and may support the wafer. Also, the support unit 230 may support the wafer group when the second driving unit 220 accommodates the wafer group inside the processing bath 300-1 or 300-2 or takes out the wafer group to the outside of the processing bath 300-1 or 300-2 while moving in the third direction Z or its opposite direction. However, unlike the second arm A2, the support unit 230 may not play a role of rotating the wafer group in a state that it supports the wafer group. The support unit 230 and the second arm A2 will be described later with reference to FIG. 5 and the like.

The second wafer transferring unit 200 may move in the first direction X between the plurality of processing baths. For example, after the wafer group is processed in the processing bath 300-1, the second driving unit 220 may move in the third direction Z along the second rail guide 210 to take out the wafer group to the outside of the processing bath 300-1. For example, the second driving unit 220 may move in the third direction Z along the second rail guide 210 to remove the wafer group from the processing bath 300-1. Afterwards, the second wafer transferring unit 200 may move in the first direction X and be positioned on the processing bath 300-2. Then, the second driving unit 220 may move again in the opposite direction of the third direction Z to accommodate the wafer group in the processing bath 300-2. In this way, the second wafer transferring unit 200 may transfer the wafer between the plurality of processing baths, and may transfer the wafer group to the inside and the outside of the processing bath.

Although FIG. 1 shows that one second wafer transferring unit 200 is included in the wafer cleaning system 1000, the wafer cleaning system 1000 may include a plurality of second wafer transferring units 200 depending on the embodiments. For example, when the wafer cleaning system 1000 includes a plurality of processing baths and a plurality of second wafer transferring units, some second wafer transferring units may be in charge of wafer transfer between some of the plurality of processing baths, and other second wafer transferring units may transfer the wafer between several other processing baths.

According to the embodiment, the wafer cleaning system 1000 may further include a tank region AR1 and a circulation region AR2. The tank region AR1 may be a region in which a tank for refreshing before supplying the chemical liquid supplied from a factory to the inside of the processing baths 300-1 and 300-2 is disposed. The circulation region AR2 may be a region that includes an element for adjusting a temperature by circulating the chemical liquid of the chemical solution bath for a predetermined time. According to the embodiment, the wafer cleaning system 1000 may further include other elements in addition to the elements shown in FIG. 1.

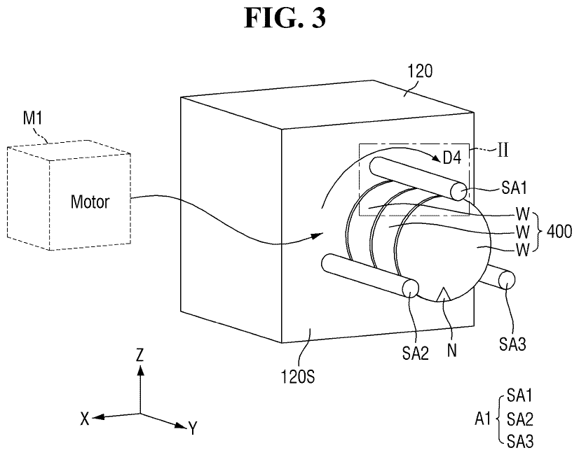

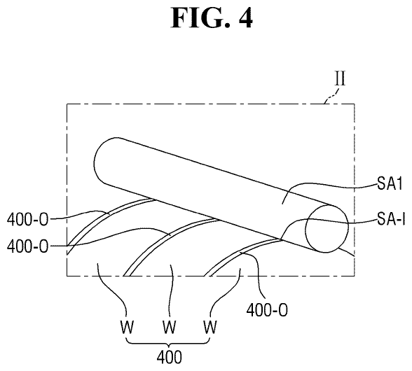

FIG. 2 is an example view illustrating a first wafer transferring unit. FIG. 3 is an enlarged view illustrating a portion I of FIG. 2. FIG. 4 is an enlarged view illustrating a portion II of FIG. 3. Hereinafter, the first wafer transferring unit 100 included in the wafer cleaning system 1000 will be described with reference to FIGS. 2 to 4.

The first arm A1 may include a plurality of sub-arms SA1, SA2, and SA3. The plurality of sub-arms SA1, SA2, and SA3 may be mounted on one surface 120S of the first driving unit 120. The plurality of sub-arms SA1, SA2, and SA3 may be disposed to form a triangle on one surface 120S of the first driving unit 120. Each of the plurality of sub-arms SA1, SA2, and SA3 may be extended lengthwise in the second direction Y, and may include a cylindrical shape. A wafer group 400 including a plurality of wafers W may be seated on the plurality of sub-arms SA1, SA2, and SA3. For example, an outer side 400-O of each of the plurality of wafers W may be in contact with and seated on an inner side SA-I of each of the plurality of sub-arms SA1, SA2, and SA3.

A motor M1 may be disposed inside the first driving unit 120. The motor M1 may be connected to the plurality of sub-arms SA1, SA2, and SA3, and may simultaneously rotate the plurality of sub-arms SA1, SA2, and SA3 with respect to the second direction Y as a central axis. Therefore, the wafer group 400 supported by the plurality of sub-arms SA1, SA2, and SA3 may rotate with the sub-arms SA1, SA2, and SA3 with respect to the second direction Y as a central axis. The plurality of sub-arms SA1, SA2, and SA3 may rotate in a fourth direction D4 corresponding to a clockwise direction or in an opposite direction of the fourth direction D4, which corresponds to a counterclockwise direction, depending on a driving method of the motor M1.

At least one wafer W among the plurality of wafers included in the wafer group 400 may include a notch N. A direction toward which the notch N of the wafer W is directed may also vary depending on the rotation of the wafer W.

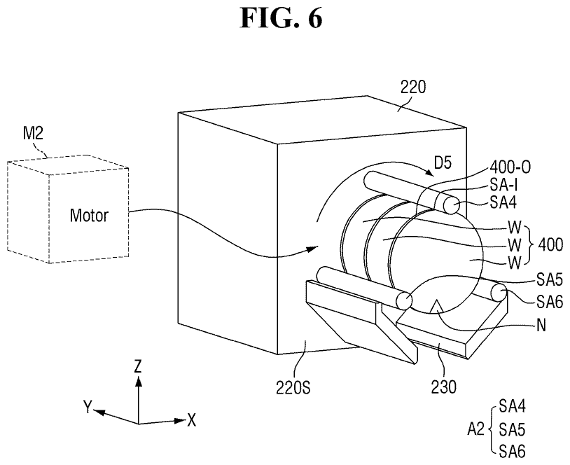

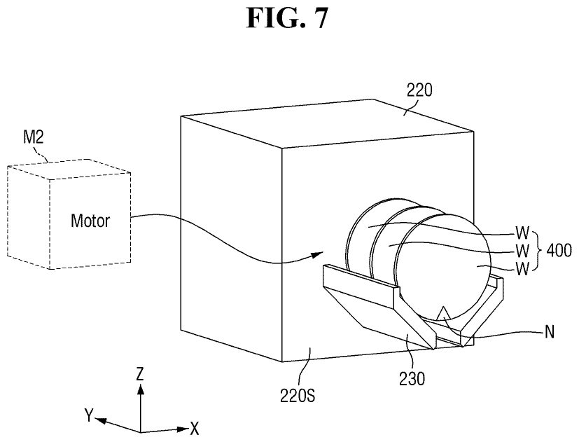

FIG. 5 is an example view illustrating a second wafer transferring unit according to some example embodiments. FIG. 6 is an enlarged view illustrating a portion III of FIG. 5. FIGS. 7 and 8 are example views illustrating a second wafer transferring unit according to some other example embodiments. Hereinafter, the second wafer transferring unit 200 included in the wafer cleaning system 1000 will be described with reference to FIGS. 5 and 8.

First, referring to FIGS. 5 and 6, the second arm A2 may include a plurality of sub-arms SA4, SA5, and SA6. The plurality of sub-arms SA4, SA5, and SA6 may be mounted on one surface 220S of the second driving unit 220. The plurality of sub-arms SA4, SA5, and SA6 may be disposed to form a triangle on one surface 220S of the second driving unit 220. Each of the plurality of sub-arms SA4, SA5, and SA6 may be extended lengthwise in the second direction Y, and may include a cylindrical shape. The wafer group 400 including a plurality of wafers W may be mounted on the plurality of sub-arms SA4, SA5, and SA6. For example, an outer side 4000 of each of the plurality of wafers W may be in contact with and seated on an inner side SA-I of each of the plurality of sub-arms SA4, SA5, and SA6.

A motor M2 may be disposed inside the second driving unit 220. The motor M2 may be connected to the plurality of sub-arms SA4, SA5, and SA6, and may simultaneously rotate the plurality of sub-arms SA4, SA5, and SA6 with respect to the second direction Y as a central axis. Therefore, the wafer group 400 supported by the plurality of sub-arms SA4, SA5, and SA6 may rotate together with the sub-arms SA4, SA5, and SA6 with respect to the second direction Y as a central axis. The plurality of sub-arms SA4, SA5, and SA6 may rotate in a fifth direction D5 corresponding to a clockwise direction or in an opposite direction of the fifth direction D5, which corresponds to a counterclockwise direction, depending on a driving method of the motor M2.

Although FIG. 5 and FIG. 6 show that both the second arm A2 and the support unit 230 are disposed on one surface of the second driving unit 220, the embodiments are not limited thereto. For example, referring to FIG. 7, only the support unit 230 may be disposed on one surface 220S of the second driving unit 220. An upper surface of the support unit 230 may support the wafer group 400. In this case, the second driving unit 220 may not include the motor M2. Therefore, the wafer group 400 may not rotate, and may be transferred in a state that the notch N of the wafer W is directed downward, and may be processed by a chemical solution or the like inside the processing baths 300-1 and 300-2 (shown in FIG. 1) in a state that the notch N of the wafer W is directed downward.

Next, referring to FIG. 8, only an arm A2 including the plurality of sub-arms SA4, SA5, and SA6 for supporting the wafer group 400 may be disposed on one surface 220S of the second driving unit 220, and the support unit 230 may not be disposed.

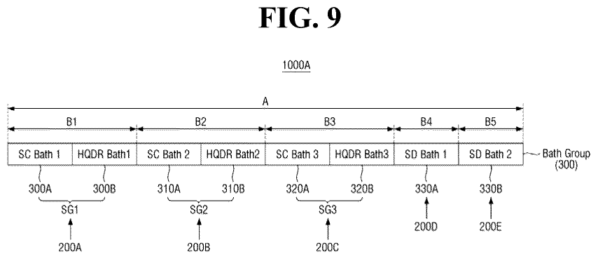

FIGS. 9 to 12 are example views illustrating a wafer cleaning system according to some example embodiments. In the following description, it is assumed that one first wafer transferring unit 100 and a plurality of second wafer transferring units 200A, 200B, 200C, 200D and 200E are included in the wafer cleaning system 1000.

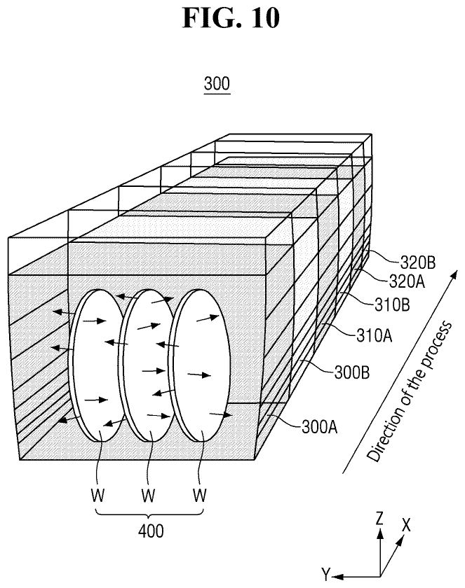

First, referring to FIG. 9 and FIG. 10, the processing bath group 300 of the wafer cleaning system 1000A may include a plurality of processing baths 300A, 300B, 310B, 310B, 320A, 320B, 330A and 330B. The processing bath group 300 may include a first standard clean (SC) processing bath 300A, a first hot quick dump rinse (HQDR) processing bath 300B, a second SC processing bath 310A, a second HQDR processing bath 310B, a third SC processing bath 320A, a third HQDR processing bath 320B, a first standard dry (SD) processing bath 330A, and a second SD processing bath 330B. Although FIG. 9 shows that the processing bath group 300 includes three SC processing baths 300A, 310A, and 320A, three HQDR processing baths 300B, 310B, and 320B, and two SD processing baths 330A and 330B, the embodiments are not limited thereto. The types and number of processing baths included in the processing bath group 300 may vary depending on the embodiments.

The first SC processing bath 300A, the second SC processing bath 310A and the third SC processing bath 320A may include the same processing liquid therein. For example, the same process for the wafer group 400 may be performed inside the first SC processing bath 300A, the second SC processing bath 310A, and the third SC processing bath 320A. For example, the first SC processing bath 300A, the second SC processing bath 310A, and the third SC processing bath 320A are chemical solution baths, and any one of a wafer cleaning process, a photoresist delamination process and an etching process may be performed for the baths.

The first HQDR processing bath 300B, the second HQDR processing bath 310B, and the third HQDR processing bath 320B each may include the same processing liquid therein. For example, the same process for the wafer group 400 may be performed inside the first HQDR processing bath 300B, the second HQDR processing bath 310B, and the third HQDR processing bath 320B. For example, the first HQDR processing bath 300B is a liquid solution bath, and a process of cleaning a wafer that has been completely processed in the first SC processing bath 300A corresponding to the chemical solution bath may be performed for the first HQDR processing bath 300B. Likewise, the second HQDR processing bath 310B is a liquid solution bath, and a process of cleaning a wafer that has been completely processed in the second SC processing bath 310A corresponding to the chemical solution bath may be performed for the second HQDR processing bath 310B. Likewise, the third HQDR processing bath 320B is a liquid solution bath, and a process of cleaning a wafer that has been completely processed in the third SC processing bath 320A corresponding to the chemical solution bath may be performed for the third HQDR processing bath 320B.

In the first SD processing bath 330A and the second SD processing bath 330B, a process of drying a wafer that has been completely processed in the SC processing bath corresponding to the chemical solution bath and the HQDR processing bath corresponding to the liquid solution bath may be performed. The first SD processing bath 330A and the second SD processing bath 330B are processing baths that perform the same role, and the wafer that has been completely processed in the SC processing bath and the HQDR processing bath may be accommodated and dried in one of the first SD processing bath 330A and the second SD processing bath 330B.

The wafer cleaning system 1000A may include a plurality of second wafer transferring units 200A, 200B, 200C, 200D and 200E. Each of the plurality of second wafer transferring units 200A, 200B, 200C, 200D and 200E may be implemented as the second wafer transferring units 200 shown in FIGS. 1 to 8.

The plurality of processing baths 300A, 300B, 310A, 310B, 320A, and 320B may be classified into a plurality of sub-groups SG1, SG2, and SG3 depending on corresponding second wafer transferring units. For example, processing baths belonging to the same sub-group may be processed by the same second wafer transferring unit, and processing baths belonging to different sub-groups may be processed by different second wafer transferring units.

For example, the first SC processing bath 300A and the first HQDR processing bath 300B may constitute the first sub-group SG1, the second SC processing bath 310A and the second HQDR processing bath 310B may constitute the second sub-group SG2, and the third SC processing bath 320A and the third HQDR processing bath 320B may constitute the third sub-group SG3.

The first sub-group SG1 may correspond to the second wafer transferring unit 200A, the second sub-group SG2 may correspond to the second wafer transferring unit 200B, and the third sub-group SG3 may correspond to the second wafer transferring unit 200C.

For example, the first SC processing bath 300A and the first HQDR processing bath 300B, which are included in the first sub-group SG1, may be included in a movement range B1 of the second wafer transferring unit 200A. The second SC processing bath 310A and the second HQDR processing bath 310B, which are included in the second sub-group SG2, may be included in a movement range B2 of the second wafer transferring unit 200B. The third SC processing bath 320A and the third HQDR processing bath 320B, which are included in the third sub-group SG3, may be included in a movement range B3 of the second wafer transferring unit 200C. The first SD processing bath 330A may be included in a movement range B4 of the second wafer transferring unit 200D, and the second SD processing bath 330B may be included in a movement range B5 of the second wafer transferring unit 200E.

For example, the second wafer transferring unit 200A may be in charge of the first SC processing bath 300A and the first HQDR processing bath 300B, which are included in the first sub-group SG1, to move the wafer group 400 subjected to the wafer processing process from the first SC processing bath 300A to the first HQDR processing bath 300B. The wafer group 400 subjected to the wafer processing process in the first HQDR processing bath 300B may move from the second wafer transferring unit 200A to the first wafer transferring unit 100.

Afterwards, the first wafer transferring unit 100 may move toward the second SC processing bath 310A in a state that it supports the wafer group 400 by using the first arm A1. The first wafer transferring unit 100 may transfer the wafer group 400 to the second wafer transferring unit 200B positioned on the second SC processing bath 310A, and the second wafer transferring unit 200B may accommodate the wafer group 400 in the second SC processing bath 310A in a state that it supports the wafer group 400 in the second arm A2 or the support unit 230. Then, the second wafer transferring unit 200B may move the wafer group 400 subjected to the wafer processing process from the second SC processing bath 310A to the second HQDR processing bath 310B. The wafer group 400 subjected to the wafer processing process in the second HQDR processing bath 310B may move back from the second wafer transferring unit 200B to the first wafer transferring unit 100.

In this way, the second wafer transferring unit 200C may move between the third SC processing bath 320A and the third HQDR processing bath 320B, which are included in the third sub-group SG3, and the first wafer transferring unit 100 may move the wafer group 400 among the sub-groups SG1, SG2, and SG3, the first SD processing bath 330A and the second SD processing bath 330B. The second wafer transferring unit 200D may accommodate the wafer group 400 completely processed in one of the SC processing baths 300A, 310A, and 320A and the HQDR processing baths 300B, 310B, and 320B into the first SD processing bath 330A. Also, the second wafer transferring unit 200E may accommodate the wafer group 400 completely processed in one of the SC processing baths 300A, 310A, and 320A and the HQDR processing baths 300B, 310B, and 320B into the second SD processing bath 330B.

As described above, the wafer group 400 may be moved by at least one of the first wafer transferring units 100 or the second wafer transferring units 200A, 200B, 200C, 200D, and 200E and accommodated in at least one of the plurality of processing baths 300A, 300B, 310A, 310B, 320B, 320B, 330A, and 330B included in the processing bath group 300 so that the wafer processing process may be performed.

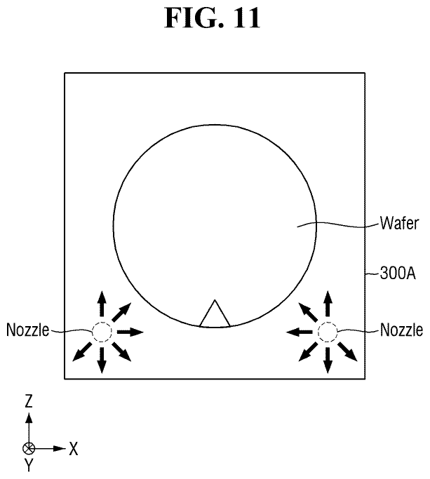

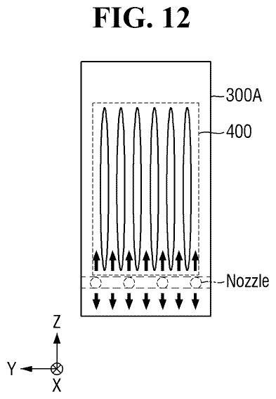

Next, FIGS. 11 and 12 are views illustrating that the wafer group 400 is accommodated inside the first SC processing bath 300A. Referring to FIGS. 11 and 12, a fluid for processing the wafer group 400 may be injected from a nozzle positioned below the first SC processing bath 300A. In this case, since the nozzle from which the fluid is injected is disposed below the first SC processing bath 300A, process distribution of the wafer completely processed inside the first SC processing bath 300A may not be uniform in a lower region of a wafer surface and an upper region of the wafer surface.

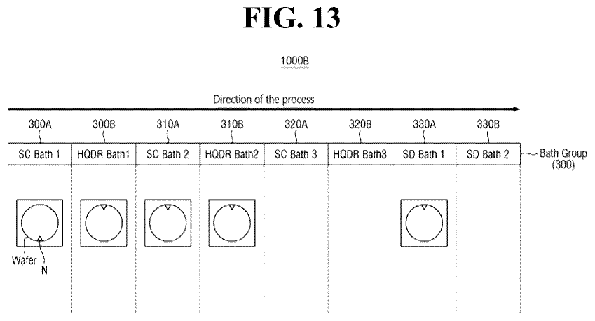

FIGS. 13 to 26 are example views illustrating a wafer cleaning operation of a wafer cleaning system according to some example embodiments.

First, FIG. 13 is a view illustrating a change in a direction toward which the notch N of at least one wafer W included in the wafer group 400 is directed, when a wafer cleaning process is performed in a wafer cleaning system 1000B. In the following description, a case that the wafer group 400 is cleaned by passing through the first SC processing bath 300A, the first HQDR processing bath 300B, the second SC processing bath 310A, the second HQDR processing bath 310B, and the first SD processing bath 330A among the plurality of processing baths 300A, 300B, 310A, 310B, 320A, 320B, 330A, and 330B will be described by way of example.

When the wafer group 400 is processed inside the first SC processing bath 300A, the notch N of the wafer W may be directed downward. Afterwards, when the wafer group 400 completely processed inside the first SC processing bath 300A is processed inside the first HQDR processing bath 300B, the second SC processing bath 310A, the second HQDR processing bath 310B, and the first SD processing bath 330A, the notch N of the wafer W may be directed upward.

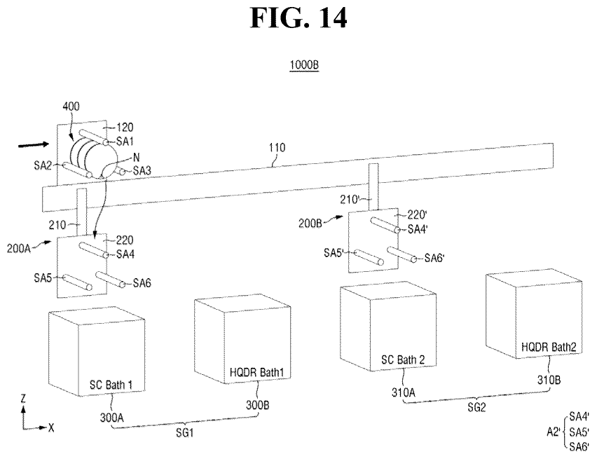

Hereinafter, a wafer cleaning operation of the wafer cleaning system 1000B shown in FIG. 13 will be described with reference to FIGS. 14 to 26.

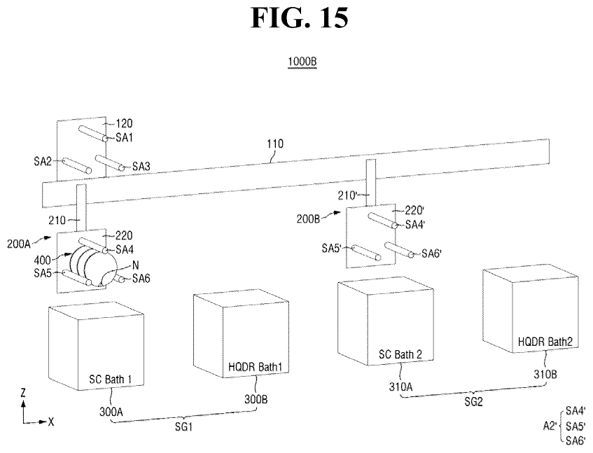

First, referring to FIGS. 14 and 15, the first driving unit 120 may move in the first direction X along the first rail guide 110 and then stop when it is positioned in front of the second wafer transferring unit 200A. In this case, the plurality of sub-arms SA1, SA2, and SA3 of the first arm A1 formed in front of the first driving unit 120 may support the wafer group 400 in the plurality of sub-arms SA1, SA2, and SA3 of the first arm A1 such that the notch N of the wafer W is directed toward the opposite direction of the third direction Z.

When the first driving unit 120 is positioned in front of the second wafer transferring unit 200A, the first driving unit 120 may transfer the wafer group 400 from the first arm A1 to the second arm A2. The plurality of sub-arms SA4, SA5, and SA6 of the second arm A2, which have received the wafer group 400 from the first arm A1, may support the wafer group 400 as the notch N of the wafer W is directed toward the opposite direction of the third direction Z. Meanwhile, the second SC processing bath 310A included in the second sub-group SG2 and the second wafer transferring unit 200B that is in charge of the second HQDR processing bath 310B may be positioned on the second SC processing bath 310A.

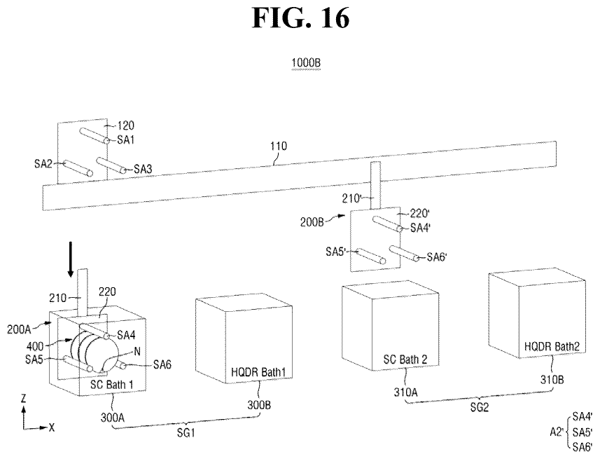

Next, referring to FIG. 16, the second driving unit 220 may move in the opposite direction of the third direction Z along the second rail guide 210 to accommodate the wafer group 400 in the first SC processing bath 300A. The wafer group 400 accommodated in the first SC processing bath 300A may be processed by a chemical solution contained in the first SC processing bath 300A.

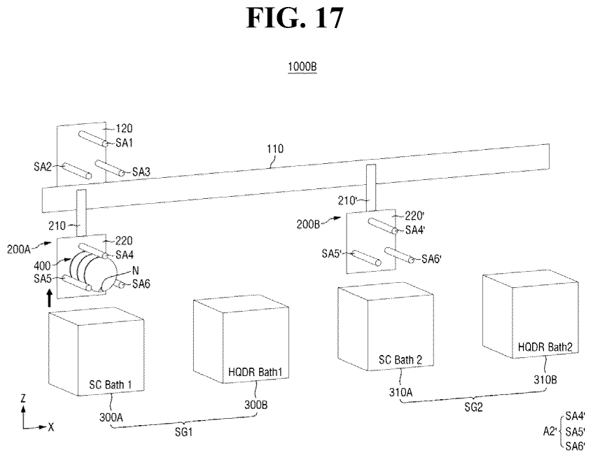

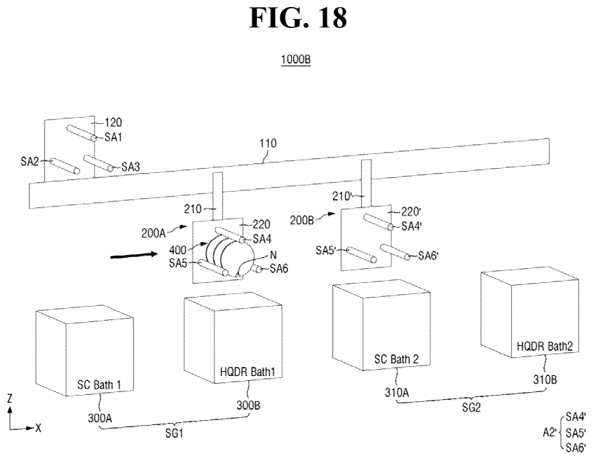

Next, referring to FIGS. 17 and 18, after the processing is completed in the first SC processing bath 300A, the second driving unit 220 may move in the third direction Z along the second rail guide 210 to take out the wafer group 400 to the outside of the first SC processing bath 300A. For example, the second driving unit 220 may move in the third direction Z along the second rail guide 210 to remove the wafer group 400 from the first SC processing bath 300A. Subsequently, the second wafer transferring unit 200A may move along the first direction X to position the wafer group 400 completely processed in the first SC processing bath 300A on the first HQDR processing bath 300B.

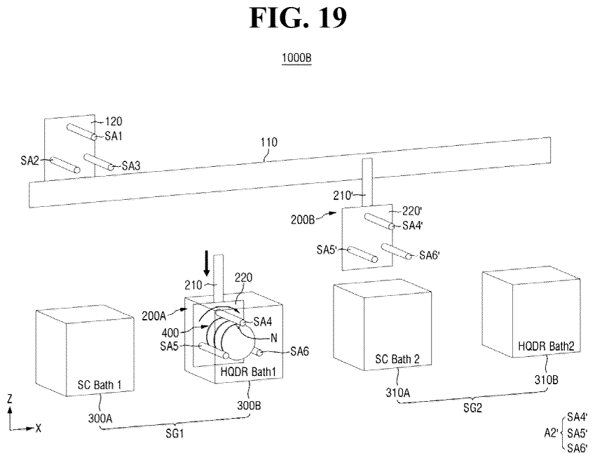

Next, referring to FIG. 19, the second driving unit 220 of the second wafer transferring unit 200A positioned on the first HQDR processing bath 300B may move in the opposite direction of the third direction Z along the second rail guide 210 to accommodate the wafer group 400 in the first HQDR processing bath 300B. While the HQDR process is performed inside the first HQDR processing bath 300B, the motor M2 (shown in FIG. 6) inside the second driving unit 220 may rotate the plurality of sub-arms SA4, SA5, and SA6 with respect to the second direction Y as a central axis. With the rotation of the plurality of sub-arms SA4, SA5, and SA6, the wafer group 400 supported by the plurality of sub-arms SA4, SA5, and SA6 may rotate together with the plurality of sub-arms SA4, SA5, and SA6 with respect to the second direction Y as a central axis. Therefore, the notch N of the wafer W may rotate as much as 180° so that it may be directed toward the third direction Z.

However, I although FIGS. 13 and 19 show that the wafer group 400 is rotated using the second wafer transferring unit 200A so that there is a difference of 180° in the direction toward which the notch N of the wafer W is directed, the embodiments are not limited thereto. An angle at which the second wafer transferring unit 200A rotates the wafer group 400 may vary depending on the embodiments.

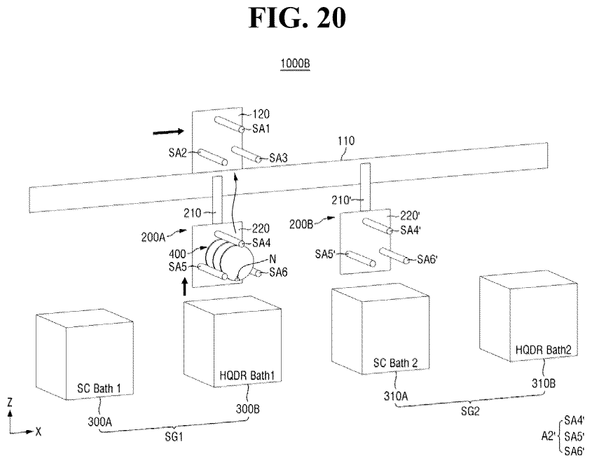

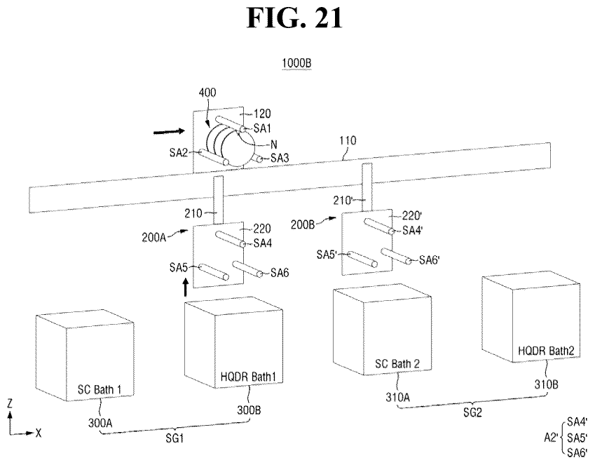

Next, referring to FIGS. 20 and 21, after the processing is completed inside the first HQDR processing bath 300B, the second driving unit 220 may move in the third direction Z along the second rail guide 210 to take out the wafer group 400 to the outside of the first HQDR processing bath 300B. For example, the second driving unit 220 may move in the third direction Z along the second rail guide 210 to remove the wafer group 400 from the first HQDR processing bath 300B. The first driving unit 120 may further move in the first direction X along the first rail guide 110. When the first driving unit 120 moves along the first direction X and is positioned on the first HQDR processing bath 300B, the second driving unit 220 may again transfer the wafer group 400 from the second arm A2 to the first arm A1. Therefore, the plurality of sub-arms SA1, SA2, and SA3 mounted on the first driving unit 120 may support the wafer group 400.

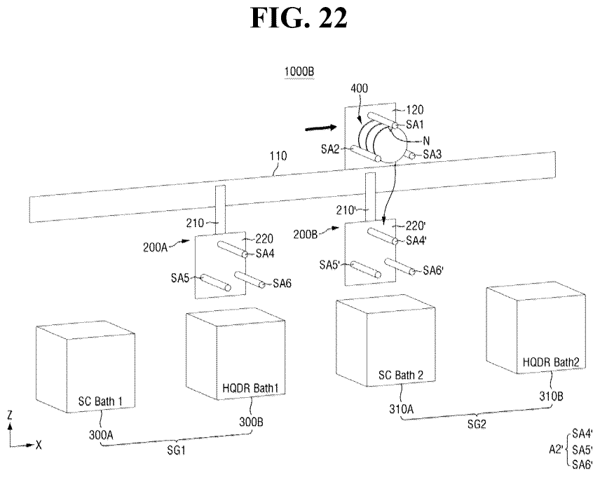

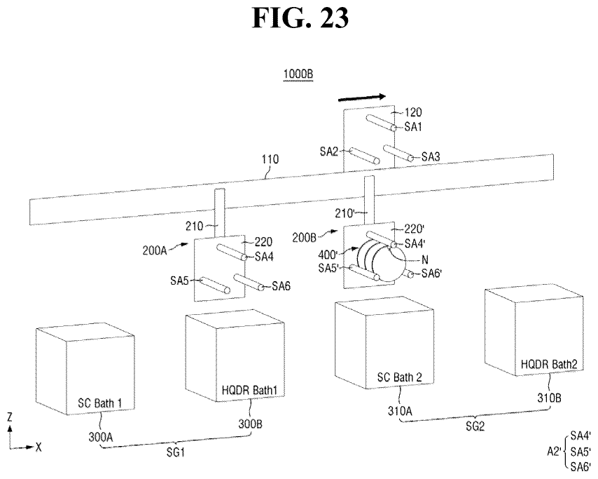

Next, referring to FIGS. 22 and 23, the first driving unit 120 that has received the wafer group 400 from the second driving unit 220 may further move in the first direction X along the first rail guide 110. When the first driving unit 120 moves along the first direction X and is positioned on the second SC processing bath 310A, the first driving unit 120 may transfer the wafer group 400 from the first arm A1 to a plurality of sub-arms SA4′, SA5′, and SA6′ of the second wafer transferring unit 200B. The plurality of sub-arms SA4′, SA5′, and SA6′ of the second wafer transferring unit 200B, which have received the wafer group 400 from the first arm A1, may support the wafer group 400 in a state that the wafer group is rotated inside the first HQDR processing bath 300B, that is, may support the wafer group 400 in a state that the notch N is directed toward the third direction Z. Meanwhile, the second wafer transferring unit 200A may be still positioned on the first HQDR processing bath 300B.

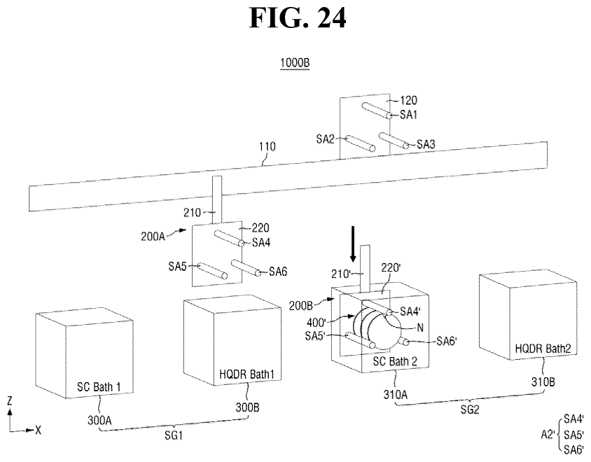

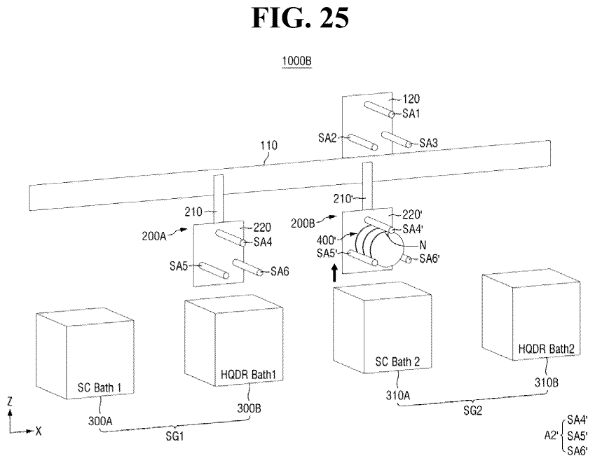

Next, referring to FIGS. 24 and 25, a second driving unit 220′ of the second wafer transferring unit 200B may move in the opposite direction of the third direction Z along a second rail guide 210′ to accommodate the wafer group 400 in the second SC processing bath 310A. The wafer group 400 accommodated in the second SC processing bath 310A may be processed by the chemical solution contained in the second SC processing bath 310A. Subsequently, after the processing is completed in the second SC processing bath 310A, the second driving unit 220′ may move in the third direction Z along the second rail guide 210′ to take out the wafer group 400 to the outside of the second SC processing bath 310A. For example, the second driving unit 220′ may move in the third direction Z along the second rail guide 210′ to remove the wafer group 400 from the second SC processing bath 310A.

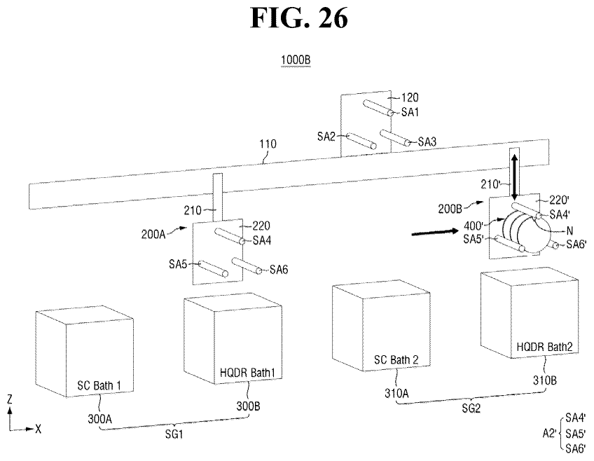

Next, referring to FIG. 26, the second wafer transferring unit 200B may move in the first direction X to position the wafer group 400 completely processed in the second SC processing bath 310A on the second HQDR processing bath 310B. Subsequently, the second driving unit 220′ may move in the opposite direction of the third direction Z along the second rail guide 210′ to accommodate the wafer group 400 into the second HQDR processing bath 310B, and then may process the wafer group 400 to be subjected to HQDR processing. Afterwards, the second driving unit 220′ may move again in the third direction Z to take out the wafer group 400 to the outside of the second HQDR processing bath 310B. For example, the second driving unit 220′ may move again in the third direction Z to remove the wafer group 400 from the second HQDR processing bath 310B. Subsequently, the wafer group 400 may be moved into the first SD processing bath 330A by the second wafer transferring unit 200D (shown in FIG. 9) and then may be dried.

In this way, the wafer group 400 may be rotated by the second wafer transferring unit 200A so that there is a difference of 180° between the direction toward which the notch N of the wafer W is directed inside the first SC processing bath 300A and the direction toward which the notch N of the wafer W is directed inside the second SC processing bath 310A. As a result, the wafer may be cleaned so that the process distribution on the surface of the wafer that has passed through the wafer cleaning system 1000B may be uniform as a whole.

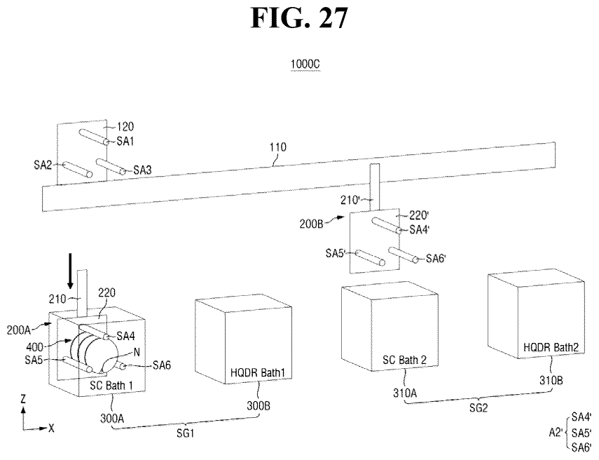

FIGS. 27 to 29 are example views illustrating a wafer cleaning operation of a wafer cleaning system according to some other example embodiments. Hereinafter, the redundant description of the previous embodiments will be omitted, and the following description will be based on differences from the previous embodiments.

FIG. 27 is a view illustrating a wafer cleaning process is performed in a wafer cleaning system 1000C. First, referring to FIG. 27, the second wafer transferring unit 200A may move in the opposite direction of the third direction Z along the second rail guide 210 to accommodate the wafer group 400 in the first SC processing bath 300A. In this case, the notch N of the wafer W may be in a state that it is directed toward the opposite direction of the third direction Z.

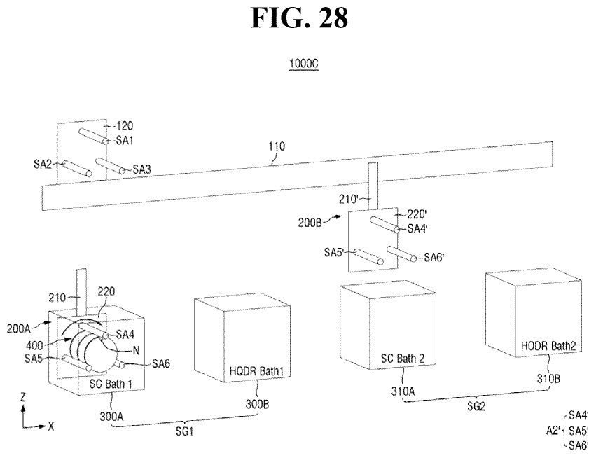

Subsequently, referring to FIG. 28, after the wafer group 400 is completely processed by the chemical solution inside the first SC processing bath 300A, the motor M2 (shown in FIG. 6) inside the second driving unit 220 may rotate the plurality of sub-arms SA4, SA5, and SA6 with respect to the second direction Y as a central axis before taking out the wafer group 400 to the outside of the first SC processing bath 300A. With the rotation of the plurality of sub-arms SA4, SA5, and SA6, the wafer group 400 supported by the plurality of sub-arms SA4, SA5, and SA6 may rotate together with the plurality of sub-arms SA4, SA5, and SA6 with respect to the second direction Y as a central axis. Therefore, the notch N of the wafer W may rotate as much as 180° so that it may be directed toward the third direction Z.

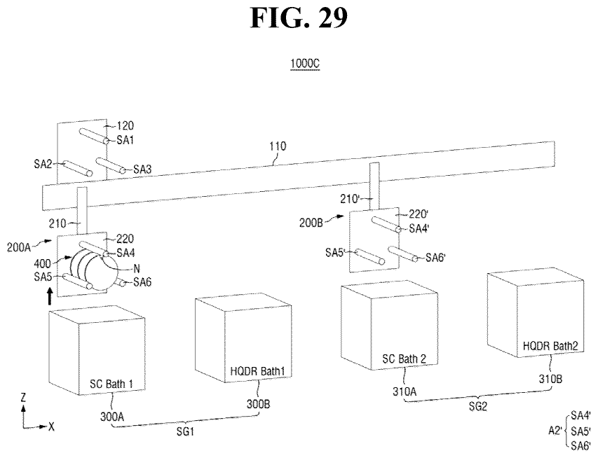

Next, referring to FIG. 29, after the processing is completed inside the first SC processing bath 300A, the second driving unit 220 may move in the third direction Z along the second rail guide 210 to take out the wafer group 400 to the outside of the first SC processing bath 300A. For example, the second driving unit 220 may move in the third direction Z along the second rail guide 210 to remove the wafer group 400 from the first SC processing bath 300A.

As described above, the second wafer transferring unit 200A may rotate the wafer group 400 inside the first SC processing bath 300A in which a cleaning process using a chemical solution is performed, rather than inside the first HQDR processing bath 300B in which HQDR process is performed. Meanwhile, although the wafer group 400 has been described with reference to FIG. 28 as rotating inside the first SC processing bath 300A after being completely processed by the chemical solution inside the first SC processing bath 300A, the embodiments are not limited thereto. According to the embodiments, the second wafer transferring unit 200A may rotate the wafer group 400 while the wafer group 400 is processed by the chemical solution inside the first SC processing bath 300A, or immediately before the wafer group 400 is completely processed by the chemical solution inside the first SC processing bath 300A.

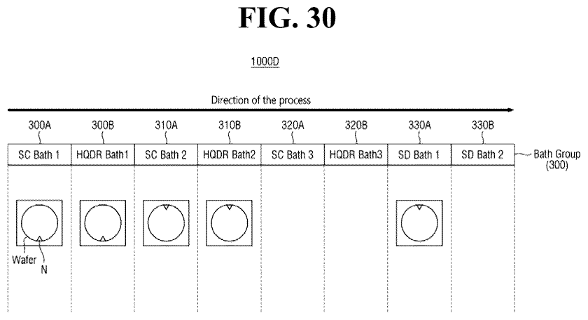

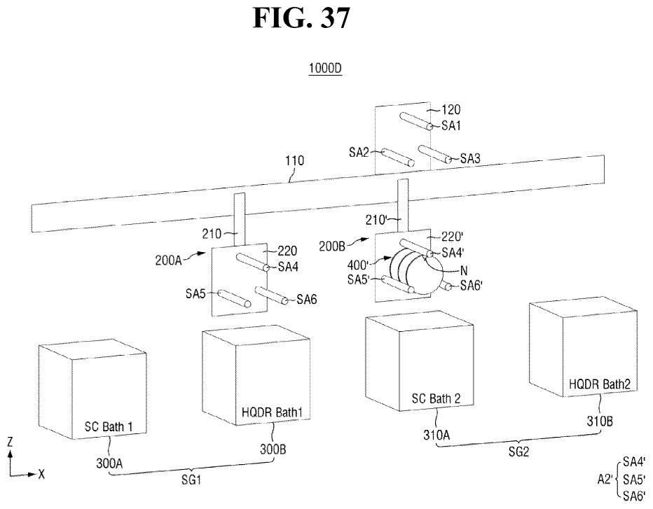

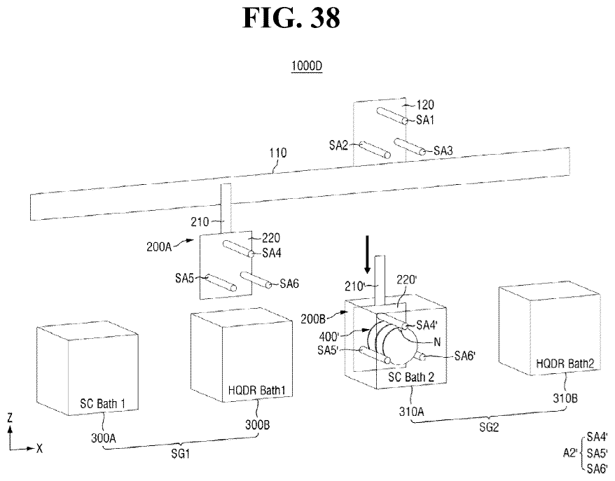

FIGS. 30 to 38 are example views illustrating a wafer cleaning operation of a wafer cleaning system according to some other example embodiments.

First, FIG. 30 is a view illustrating a change in a direction toward which the notch N of at least one wafer W included in the wafer group 400 is directed, when a wafer cleaning process is performed in a wafer cleaning system 1000D. In the following description, a case that the wafer group 400 is cleaned by passing through the first SC processing bath 300A, the first HQDR processing bath 300B, the second SC processing bath 310A, the second HQDR processing bath 310B, and the first SD processing bath 330A among the plurality of processing baths 300A, 300B, 310A, 310B, 320A, 320B, 330A, and 330B will be described by way of example.

When the wafer group 400 is processed inside the first SC processing bath 300A, the notch N of the wafer W may be directed downward. Afterwards, when the wafer group 400 completely processed inside the first SC processing bath 300A is subsequently processed inside the first HQDR processing bath 300B, the notch N of the wafer W may be directed downward as above. Afterwards, when the wafer group 400 completely processed inside the first HQDR processing bath 300B is subsequently processed inside the second SC processing bath 310A, the second HQDR processing bath 310B, and the first SD processing bath 330A, the notch N of the wafer W may be directed upward.

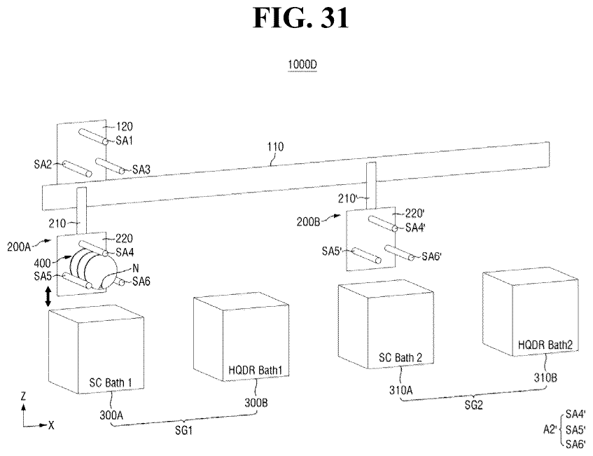

Hereinafter, a wafer cleaning operation of a wafer cleaning system 1000D shown in FIG. 30 will be described with reference to FIGS. 31 to 38. Hereinafter, the redundant description of the previous embodiments will be omitted, and the following description will be based on differences from the previous embodiments.

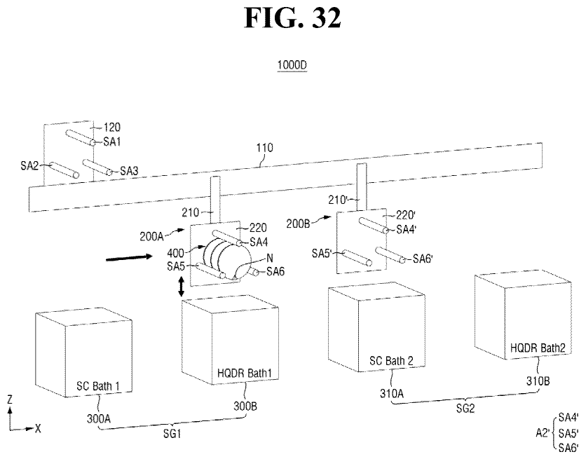

First, referring to FIGS. 31 and 32, the second wafer transferring unit 200A may accommodate the wafer group 400 into the first SC processing bath 300A so that the wafer group 400 may be processed by the chemical solution contained in the first SC processing bath 300A. After the wafer group 400 is processed inside the first SC processing bath 300A, the second wafer transferring unit 200A may accommodate the wafer group 400 into the first HQDR processing bath 300B so that the wafer group 400 may be processed to be subjected to HQDR processing inside the first HQDR processing bath 300B. After the wafer group 400 is completely processed inside the first HQDR processing bath 300B, the second wafer transferring unit 200A may take out the wafer group 400 to the outside of the first HQDR processing bath 300B. For example, the second wafer transferring unit 200A may remove the wafer group 400 from the first HQDR processing bath 300B.

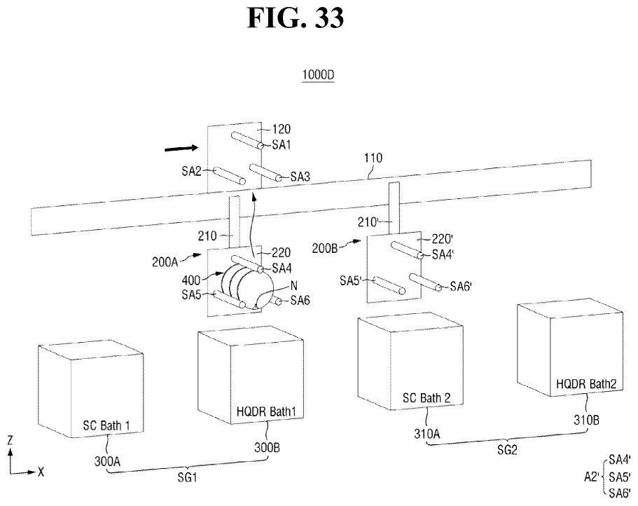

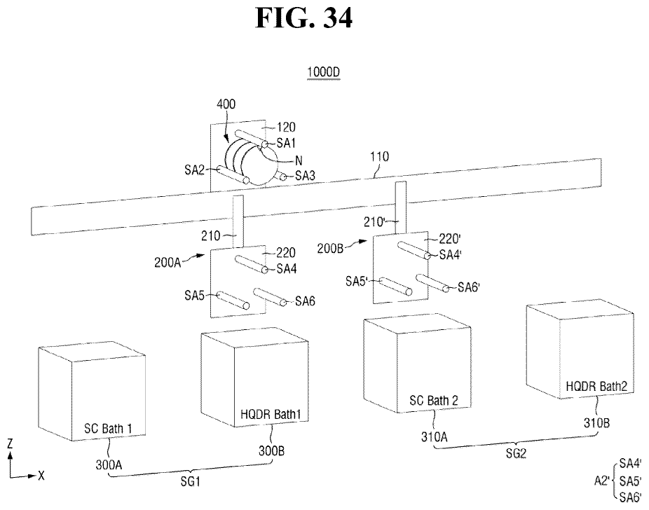

Next, referring to FIGS. 33 and 34, the first driving unit 120 may move in the first direction X along the first rail guide 110. When the first driving unit 120 is positioned on the first HQDR processing bath 300B, the second driving unit 220 may transfer the wafer group 400 from the second arm A2 to the first arm A1. In this case, the plurality of sub-arms SA1, SA2, and SA3 of the first arm A1 may support the wafer group 400 in a state that the notch N is directed toward the opposite direction of the third direction Z.

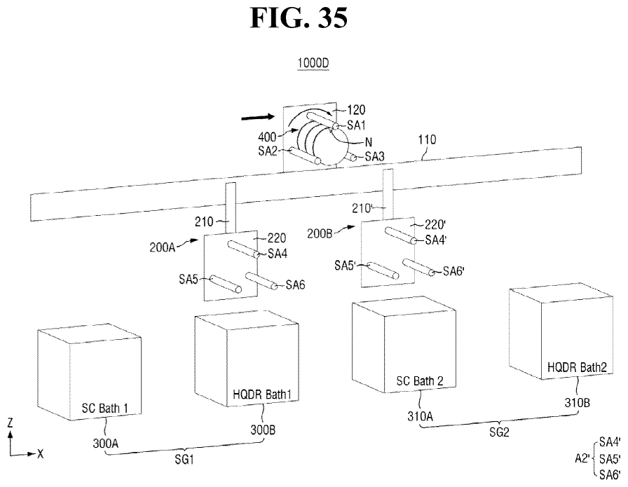

Next, referring to FIG. 35, the first driving unit 120 may move in the first direction X along the first rail guide 110 in a state that it supports the wafer group 400 with the plurality of sub-arms SA1, SA2, and SA3. While the first driving unit 120 moves along the first rail guide 110, the motor M1 (shown in FIG. 3) inside the first driving unit 120 may rotate the plurality of sub-arms SA1, SA2, and SA3 with respect to the second direction Y as a central axis. According to the rotation of the plurality of sub-arms SA1, SA2, and SA3, the wafer group 400 supported by the plurality of sub-arms SA1, SA2, and SA3 may rotate together with the plurality of sub-arms SA1, SA2, and SA3 with respect to the second direction Y as a central axis. Therefore, the notch N of the wafer W may rotate as much as 180° so that it may be directed toward the third direction Z.

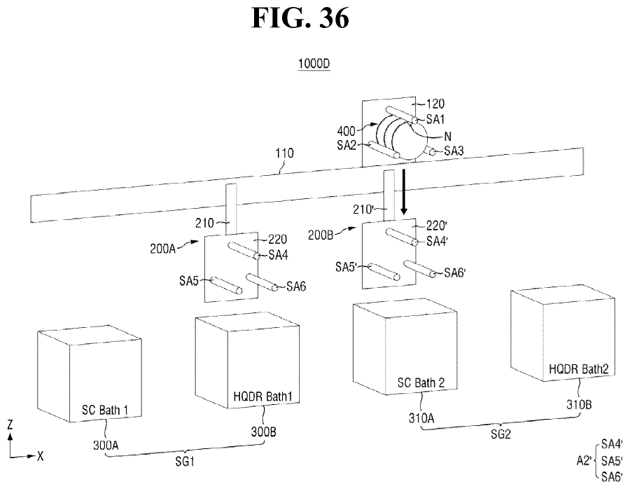

Next, referring to FIGS. 36 to 38, after the wafer group 400 is rotated, the first driving unit 120 may further move in the first direction X along the first rail guide 110 and be disposed on the second SC processing bath 310A. Afterwards, the first driving unit 120 may transfer the wafer group 400 of the rotated state from the first arm A1 to the plurality of sub-arms SA4′, SA5′, and SA6′ of the second wafer transferring unit 200B. The plurality of sub-arms SA4′, SA5′, and SA6′ of the second wafer transferring unit 200B, which have received the wafer group 400 from the first arm A1, may support the wafer group 400 in a state that the notch N of the wafer W is directed toward the third direction Z. Subsequently, the second driving unit 220′ may move in the opposite direction of the third direction Z along the second rail guide 210′ to accommodate the wafer group 400 in the second SC processing bath 310A. The wafer group 400 accommodated in the second SC processing bath 310A may be processed by the chemical solution contained in the second SC processing bath 310A.

In this way, the wafer group 400 may be rotated by the first wafer transferring unit 100 so that there is a difference of 180° between the direction toward which the notch N of the wafer W is directed inside the first SC processing bath 300A and the direction toward which the notch N of the wafer W is directed inside the second SC processing bath 310A. As a result, the wafer may be cleaned so that the process distribution on the surface of the wafer that has passed through the wafer cleaning system 1000D may be uniform as a whole.

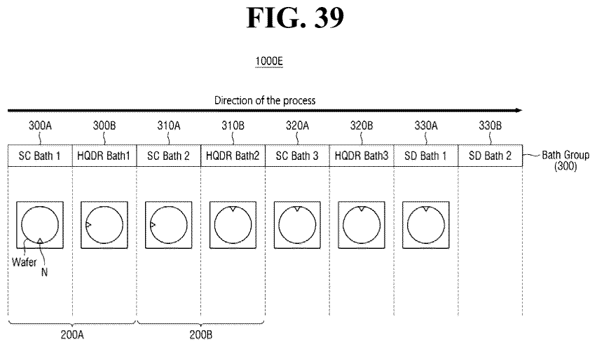

FIG. 39 is an example view illustrating a wafer cleaning operation of a wafer cleaning system according to some other example embodiments.

Referring to FIG. 39, the wafer group 400 may be rotated by the first wafer transferring unit 100 and/or the second wafer transferring units 200A and 200B two or more times in a wafer cleaning process using a wafer cleaning system 1000E.

For example, the notch N of the wafer W may be directed downward inside the first SC processing bath 300A. Afterwards, the wafer group 400 may be rotated by the second wafer transferring unit 200A as much as 90° inside the first HQDR processing bath 300B. Therefore, a region of a wafer surface in which a cleaning process is most actively performed by spray of a fluid from a nozzle positioned below the first SC processing bath 300A when the wafer group 400 is processed by the chemical solution inside the first SC processing bath 300A may be different from a region of a wafer surface in which a cleaning process is most actively performed by spray of a fluid from a nozzle positioned below the second SC processing bath 310A when the wafer group 400 is processed by the chemical solution inside the second SC processing bath 310A.

Afterwards, the wafer group 400 may be further rotated as much as 90° in the same direction by the second wafer transferring unit 200B inside the second HQDR processing bath 310B. Therefore, there may be a difference of 180° in the direction toward which the notch N of the wafer W is directed between when the wafer group 400 is processed inside the first SC processing bath 300A and when the wafer group 400 is processed inside the third SC processing bath 320A. Furthermore, a point of a wafer surface in which a cleaning process is most actively performed by spray of a fluid from a nozzle positioned below the second SC processing bath 310A when the wafer group 400 is processed by the chemical solution inside the second SC processing bath 310A may be different from a point of a wafer surface in which a cleaning process is most actively performed by spray of a fluid from a nozzle positioned below the third SC processing bath 320A when the wafer group 400 is processed by the chemical solution inside the third SC processing bath 320A. Therefore, imbalance in the process distribution (or dispersion) of the wafer surface that has passed through the wafer cleaning system 1000 may be mitigated.

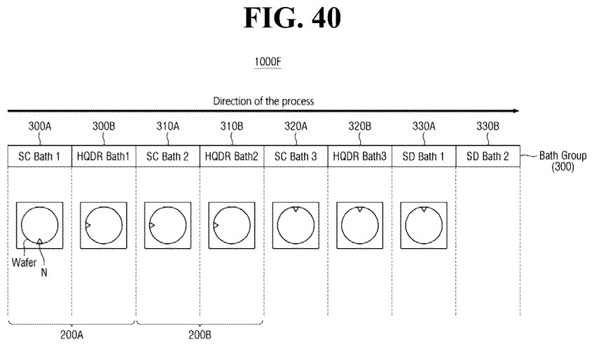

FIG. 40 is an example view illustrating a wafer cleaning operation of a wafer cleaning system according to some other example embodiments.

Referring to FIG. 40, when the wafer group 400 is rotated two or more times in a wafer cleaning process using a wafer cleaning system 1000F, the first wafer transferring unit 100 and the second wafer transferring unit 200A may be mixed to rotate the wafer group 400. For example, when the wafer group 400 is firstly rotated inside the first HQDR processing bath 300B, the wafer group 400 may be rotated using the second wafer transferring unit 200A. Then, when the wafer group 400 is secondly rotated, while the first wafer transferring unit 100 moves the wafer group 400 that has been processed inside the second HQDR processing bath 310B in the first direction X along the first rail guide 110, the wafer group 400 may be rotated using the motor M1 (shown in FIG. 3) included in the first driving unit 120.

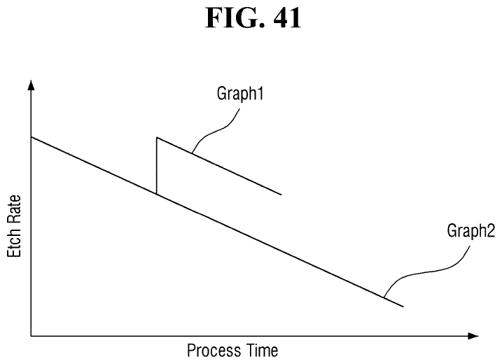

FIG. 41 is an example view illustrating an effect of a wafer cleaning system according to some example embodiments.

Referring to FIG. 41, graph 1 is a graph showing a change trend of an etch rate according to a process time when a wafer is etched using the plurality of SC processing baths (for example, the first SC processing bath 300A and the second SC processing bath 310A) included in the processing bath group 300. In contrast, graph 2 is a graph showing a change trend of an etch amount according to a process time when a wafer is etched using only one SC processing bath (for example, the first SC processing bath 300A) among the plurality of SC processing baths included in the processing bath group 300.

In some embodiments, an etching process for the wafer group 400 may be performed inside each of the first SC processing bath 300A and the second SC processing bath 310A, which include the same processing liquid therein. Also, the wafer group 400 may be rotated so that the direction toward which the notch N of the wafer W is directed when the etching process is performed inside the first SC processing bath 300A is different from the direction toward which the notch N of the wafer W is directed when the etching process is performed inside the second SC processing bath 310A.

In this way, after the wafer group 400, which has been primarily etched inside the first SC processing bath 300A, moves to the second SC processing bath 310A, the etching process is secondarily performed for the wafer group 400, so that the decrease in the etch amount due to by-products accumulated inside the first SC processing bath 300A may be mitigated.

Although the embodiments of the present disclosure have been described with reference to the accompanying drawings, the present disclosure is not limited to the above embodiments and may be implemented in various different forms. Those of ordinary skill in the technical field to which the present disclosure belongs will be able to understand that the present disclosure may be implemented in other specific forms without changing the technical idea or essential characteristics of the present disclosure. Therefore, it should be understood that the embodiments as described above are not restrictive but illustrative in all respects.

What is claimed is:

1. A wafer cleaning system comprising:
a processing bath group including a first Standard Clean (SC) processing bath, a first Hot Quick Dump Rinse (HQDR) processing bath, and a second SC processing bath, which are disposed side by side in a first direction; and
a first wafer transferring unit including a first rail guide extended in the first direction and a first driving unit mounted on the first rail guide and configured to move in the first direction along the first rail guide, the first driving unit including a first arm configured to support a wafer group and rotate in a state that it supports the wafer group; and
a second wafer transferring unit including a second rail guide extended in a second direction intersecting the first direction and a second driving unit mounted on the second rail guide and configured to move in the second direction along the second rail guide, the second driving unit including a support unit configured to support the wafer group by receiving the wafer group from the first arm,
wherein the first wafer transferring unit is configured to rotate the wafer group in a fourth direction with respect to a third direction intersecting the first and second directions as a central axis while moving the wafer group cleaned in the first SC processing bath and the first HQDR processing bath toward the second SC processing bath along the first direction.

2. The wafer cleaning system of claim 1,
wherein the first arm includes a first sub-arm, a second sub-arm, and a third sub-arm,
wherein the first to third sub-arms are mounted on the first driving unit and respectively extended from the first driving unit in the third direction, and
wherein each of the first sub-arm, the second sub-arm, and the third sub-arm includes an inner side on which each outer side of a plurality of wafers included in the wafer group is seated.

3. The wafer cleaning system of claim 1,
wherein the first arm includes a first sub-arm, a second sub-arm and a third sub-arm, which are mounted on the first driving unit, and
wherein the first driving unit includes a motor configured to rotate the first sub-arm, the second sub-arm, and the third sub-arm with respect to the third direction as a central axis.

4. The wafer cleaning system of claim 3, wherein each of the first sub-arm, the second sub-arm, and the third sub-arm is extended in the third direction, and is disposed to form a triangle on the first driving unit.

5. The wafer cleaning system of claim 1,
wherein the wafer group includes a plurality of wafers,
wherein at least one of the plurality of wafers includes a notch, and
wherein the first wafer transferring unit is configured to rotate the wafer with respect to the third direction as a central axis so that there is a difference of 180° between a direction of the notch in the first SC processing bath and a direction of the notch in the second SC processing bath.

6. The wafer cleaning system of claim 1,
wherein the processing bath group further includes a second HQDR processing bath disposed on the side of the second SC processing bath along the first direction, and
wherein the second wafer transferring unit is configured to move in the first direction between the first SC processing bath and the first HQDR processing bath.

7. The wafer cleaning system of claim 6, further comprising:
a third wafer transferring unit including a third rail guide extended in the second direction and a third driving unit mounted on the third rail guide and configured to move in the second direction along the third rail guide, the third driving unit including a support unit configured to support the wafer group by receiving the wafer group from the first arm,
wherein the third wafer transferring unit is configured to move in the first direction between the second SC processing bath and the second HQDR processing bath, and
wherein the third wafer transferring unit is configured to move the wafer group cleaned in the second SC processing bath toward the second HQDR processing bath along the first direction.

8. The wafer cleaning system of claim 7,
wherein the processing bath group further includes a standard dry (SD) processing bath disposed on the side of the second HQDR processing bath along the first direction, and
wherein the first wafer transferring unit is configured to move the wafer group cleaned in the second HQDR processing bath along the first direction and dispose the wafer group on the SD processing bath.

9. The wafer cleaning system of claim 1,
wherein the processing bath group further includes a third SC processing bath disposed on the side of the second SC processing bath along the first direction, and
wherein the first wafer transferring unit is configured to rotate the wafer group in the fourth direction with respect to the third direction as a central axis while moving the wafer group cleaned in the second SC processing bath toward the third SC processing bath along the first direction.

10. The wafer cleaning system of claim 1,
wherein the processing bath group further includes a third SC processing bath disposed on the side of the second SC processing bath along the first direction, and
wherein the first wafer transferring unit rotates the wafer group in an opposite direction of the fourth direction with respect to the third direction as a central axis while moving the wafer group cleaned in the second SC processing bath toward the third SC processing bath along the first direction.

11. A wafer cleaning system comprising:
a processing bath group including a first Standard Clean (SC) processing bath, a first Hot Quick Dump Rinse (HQDR) processing bath, and a second SC processing bath, which are disposed side by side in a first direction;
a first wafer transferring unit including a first rail guide extended in the first direction and a first driving unit mounted on the first rail guide and configured to move in the first direction along the first rail guide, the first driving unit including a first arm configured to support a wafer group; and
a second wafer transferring unit including a second rail guide extended in a second direction intersecting the first direction and a second driving unit mounted on the second rail guide and configured to move in the second direction along the second rail guide, the second driving unit including a second arm configured to support the wafer group by receiving the wafer group from the first arm and rotate in a state that it supports the wafer group,
wherein the second wafer transferring unit is configured to rotate the wafer group inside any one of the first SC processing bath and the first HQDR processing bath in a fourth direction with respect to a third direction intersecting the first direction and the second direction as a central axis, and
wherein the first wafer transferring unit is configured to move the wafer group cleaned in the first SC processing bath and the first HQDR processing bath toward the second SC processing bath along the first direction.

12. The wafer cleaning system of claim 11,
wherein the second arm includes a first sub-arm, a second sub-arm, and a third sub-arm,
wherein the first sub-arm, the second sub-arm, and the third sub-arm are mounted on the second driving unit and respectively extended from the second driving unit in the third direction,
wherein each of the first sub-arm, the second sub-arm, and the third sub-arm includes a first inner side on which each outer side of a plurality of wafers included in the wafer group is seated, and
wherein the second driving unit includes a first motor configured to rotate the first sub-arm, the second sub-arm, and the third sub-arm in the fourth direction with respect to the third direction as a central axis.

13. The wafer cleaning system of claim 12,
wherein the first arm includes a fourth sub-arm, a fifth sub-arm, and a sixth sub-arm,
wherein the fourth sub-arm, the fifth sub-arm, and the sixth sub-arm are mounted on the first driving unit and respectively extended from the first driving unit in the third direction,
wherein each of the fourth sub-arm, the fifth sub-arm, and the sixth sub-arm includes a second inner side on which is seated each outer side of a plurality of wafers included in the wafer group, and
wherein the first driving unit includes a second motor that rotates the fourth sub-arm, the fifth sub-arm, and the sixth sub-arm with respect to the third direction as a central axis.

14. The wafer cleaning system of claim 13, wherein the first wafer transferring unit is configured to rotate the wafer group with the third direction as a central axis while moving the wafer group cleaned in the first SC processing bath and the first HQDR processing bath toward the second SC processing bath along the first direction.

15. The wafer cleaning system of claim 11,
wherein the second wafer transferring unit is configured to move in the first direction between the first SC processing bath and the first HQDR processing bath, and
wherein the second wafer transferring unit is configured to move the wafer group cleaned in the first SC processing bath toward the first HQDR processing bath along the first direction, move the wafer group in the second direction to accommodate the wafer group into the first HQDR processing bath, and rotate the wafer group inside the first HQDR processing bath in the fourth direction with respect to the third direction as a central axis.

16. The wafer cleaning system of claim 15,
wherein the wafer group includes a plurality of wafers,
wherein at least one of the plurality of wafers includes a notch, and
wherein the second wafer transferring unit is configured to rotate the wafer so that there is a difference of 180° between a direction of the notch in the first SC processing bath and a direction of the notch in the first HQDR processing bath.

17. A wafer cleaning system comprising:
a processing bath group including a first Standard Clean (SC) processing bath, a first Hot Quick Dump Rinse (HQDR) processing bath, a second SC processing bath, and a second HQDR processing bath, which are disposed side by side in a first direction;
a first wafer transferring unit including a first rail guide extended in the first direction and a first driving unit mounted on the first rail guide and configured to move in the first direction along the first rail guide, the first driving unit including a first arm configured to support a wafer group and rotate in a state that it supports the wafer group;
a second wafer transferring unit including a second rail guide extended in a second direction intersecting the first direction and a second driving unit mounted on the second rail guide and configured to move in the second direction along the second rail guide, the second driving unit including a second arm configured to support the wafer group by receiving the wafer group from the first arm and rotate in a state that it supports the wafer group; and in
a third wafer transferring unit including a third rail guide extended in the second direction and a third driving unit mounted on the third rail guide and configured to move in the second direction along the third rail guide, the third driving unit including a third arm configured to support the wafer group by receiving the wafer group from the first arm and rotate in a state that it supports the wafer group,
wherein at least one of the first to third wafer transferring units is configured to rotate the wafer group with respect to a third direction intersecting the first direction and the second direction as a central axis.

18. The wafer cleaning system of claim 17, wherein the second wafer transferring unit is configured to move the wafer group cleaned in the first SC processing bath onto the first HQDR processing bath along the first direction, accommodate the wafer group into the first HQDR processing bath by moving the wafer group along the second direction, and rotate the wafer group inside the first HQDR processing bath with respect to the third direction as a central axis.

19. The wafer cleaning system of claim 18, wherein the third wafer transferring unit is configured to accommodate the wafer group cleaned in the first HQDR processing bath into the second SC processing bath, and rotate the wafer group inside the second SC processing bath with respect to the third direction as a central axis.

20. The wafer cleaning system of claim 18, wherein the third wafer transferring unit is configured to accommodate the wafer group cleaned in the first HQDR processing bath into the second SC processing bath, accommodate the wafer group cleaned in the second SC processing bath into the second HQDR processing bath, and rotate the wafer group inside the second HQDR processing bath with respect to the third direction as a central axis.
